(19) United States
(12) Patent Application Publication
(10) Pub. No.: US 2011/0111538 A1
(43) Pub. Date: May 12, 2011

(54) Method for forming LED phosphor resin layer

(75) Inventors: Pei-Hsuan Lan, Banciao-City (TW); Jui-Hung Chen, Taoyuan City (TW)

(73) Assignee: Forward Electronics Co., Ltd., Taipei City (TW)

(21) Appl. No.: 12/656,633

(22) Filed: Feb. 5, 2010

(30) Foreign Application Priority Data
Nov. 9, 2009 (TW) 098137896

(51) Int. Cl. H01L 33/00

(52) U.S. Cl. 438/27; 438/29; 257/E33.059; 257/E33.061

(57) ABSTRACT

A method for forming an LED phosphor resin layer includes the following steps: (A) providing an upper mold, a lower mold, and an LED support, wherein the LED support supports an LED chip; (B) securing the LED support on the lower mold; (C) providing a phosphor resin material between the LED chip and an attaching surface of the upper mold; (D) aligning the upper mold with the lower mold, such that the phosphor resin material in part contacts the LED chip and in part attaches to the attaching surface of the upper mold, and that the LED chip and the attaching surface are apart from each other at a predetermined distance; and (E) heating the phosphor resin material. Accordingly, the phosphor resin layer so formed can have a thickness and configuration well controlled and that the problem of spatial color difference can be improved.

### BACKGROUND OF THE INVENTION

1. Field of the Invention

The present invention relates to a method for forming an LED (light emitting diode), and more particularly, to a method for forming an LED phosphor resin layer having a specific thickness.

2. Description of Related Art

Currently the method for forming LED phosphor resin layers primarily adopts a measure of direct formation by simply dispensing a phosphor resin material on chips. However, the phosphor resin layers so formed not only cannot be controlled accurately in thickness, but also the thickness can hardly be more than 0.3 mm. Even if another formation technique, i.e. chip coating, is applied, there is still a similar limitation in thickness. As a result, the efficiency of LED luminance is adversely affected.

Further, as restricted by the known resin-dispensing technique, the bowl-like recess in receiving the chip is required to maintain a specific distance away from a side of the chip so as to keep the phosphor resin material at a predetermined position through its surface tension. In case the side spacing is too small, the phosphor resin material will be spilt. However, it is undesirable if the side spacing is too large. This is because the side spacing makes a greater color temperature difference at outer circle of the opti-zone (taking yellow phosphor resin with a blue LED chip as an example, the color of the outer circle tends to be yellow). In an LED structure made according to the conventional resin-dispensing formation technique, the phosphor resin layer is almost limited to be of spherical configuration.

Given the above, it is understood that the LED structure made according to the conventional method has a very high correlated color temperature difference, and this is undesirable.

### SUMMARY OF THE INVENTION

An object of the present invention is to provide a method for forming an LED phosphor resin layer so as to obtain an LED phosphor resin layer of a predetermined height and configuration.

To achieve the object, the method for forming an LED phosphor resin layer, according to the present invention, comprises the following steps:

(A) providing an upper mold, a lower mold, and an LED support, wherein the LED support supports an LED chip;

(B) securing the LED support on the lower mold;

(C) providing a phosphor resin material between the LED chip and an attaching surface of the upper mold;

(D) aligning the upper mold with the lower mold, such that the phosphor resin material in part contacts the LED chip and in part attaches to the attaching surface of the upper mold, and that the LED chip and the attaching surface are apart from each other at a predetermined distance; and

(E) heating the phosphor resin material so as to form an LED phosphor resin layer.

The attaching surface may appear as a plane, a concave, a convex, or other configuration as required when the molds are modified.

Subsequent to step (D), step (D1) may be further comprised, namely: Fixing the upper mold to the lower mold. The measure of fixing may be screwing. The predetermined distance in step (D) may be 0.4 to 0.9 mm.

Step (C) may be: Dispensing the phosphor resin material on the LED chip, or dispensing the phosphor resin material on the attaching surface.

Other objects, advantages, and novel features of the present invention will become more apparent from the following detailed description when taken in conjunction with the accompanying drawings.

### BRIEF DESCRIPTION OF THE DRAWINGS

FIG. 1 is a flowchart illustrating a method for forming an LED phosphor resin layer according to a first embodiment of the present invention;

FIG. 2 is an exploded view illustrating a hardware used in the method according to the first embodiment of the present invention;

FIG. 3 is a schematic view illustrating an LED phosphor resin layer, not configurated yet, according to the first embodiment of the present invention;

FIG. 4 is a schematic view illustrating an LED phosphor resin layer, configurated already, according to the first embodiment of the present invention;

FIG. 5 is a schematic view illustrating an LED phosphor resin layer, configurated already, according to a second embodiment of the present invention;

FIG. 6 is a schematic view illustrating an LED phosphor resin layer, configurated already, according to a third embodiment of the present invention; and

FIG. 7 is a schematic view illustrating an LED phosphor resin layer, configurated already, according to a fourth embodiment of the present invention.

### DETAILED DESCRIPTION OF THE PREFERRED EMBODIMENTS

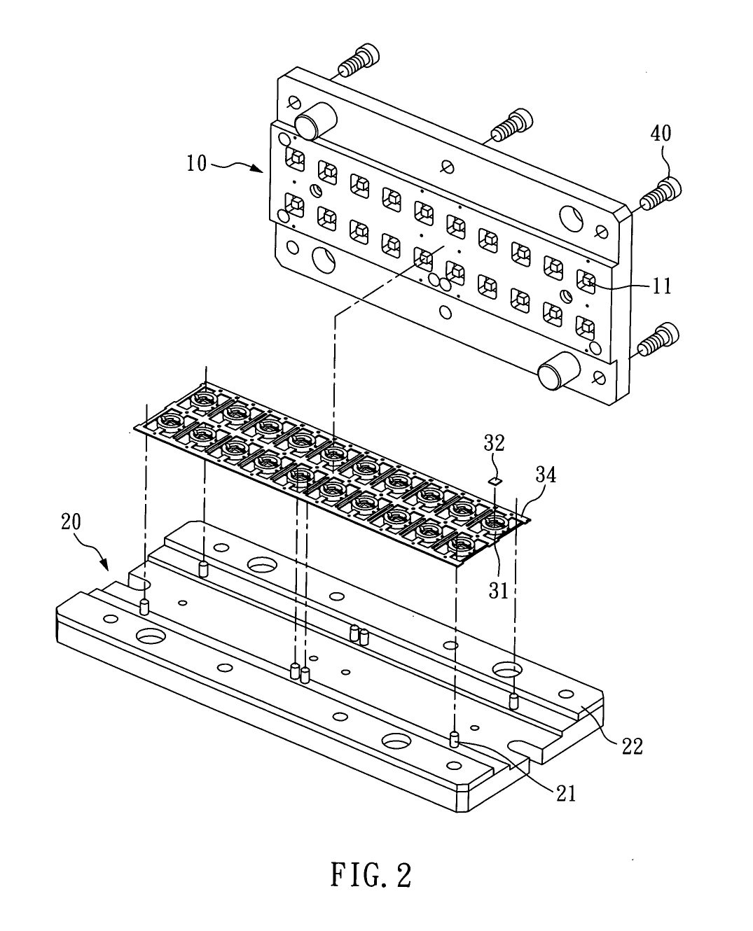

Referring to FIG. 2, an exploded view illustrating a hardware used in a method for forming an LED phosphor resin layer according to a first embodiment of the present invention, the hardware comprises an upper mold 10, a lower mold 20, a plurality of LED supports 31, arrayed in alignment, engaged with a conductive sheet 34.

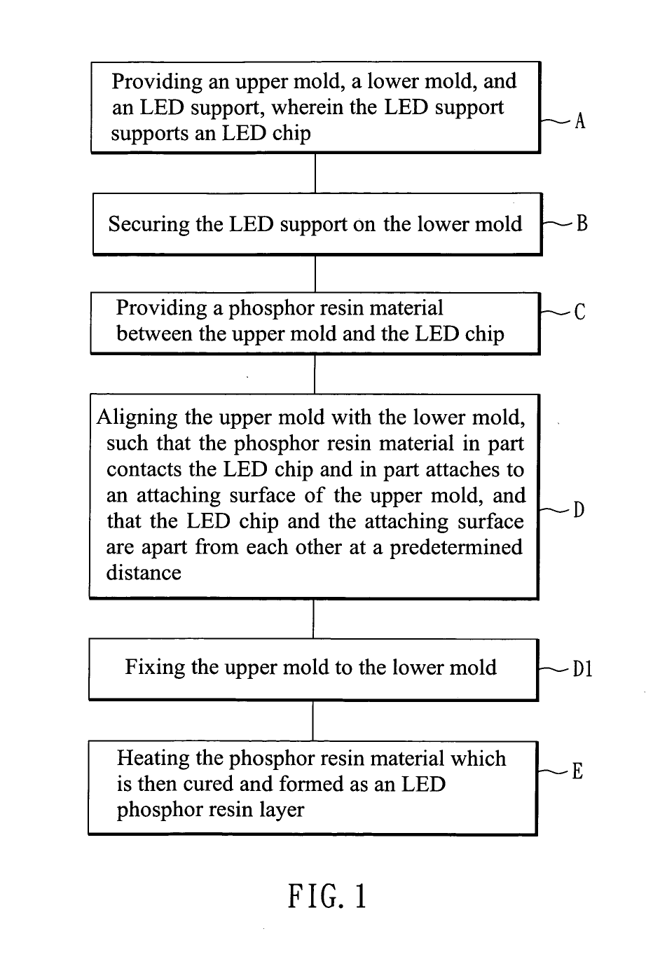

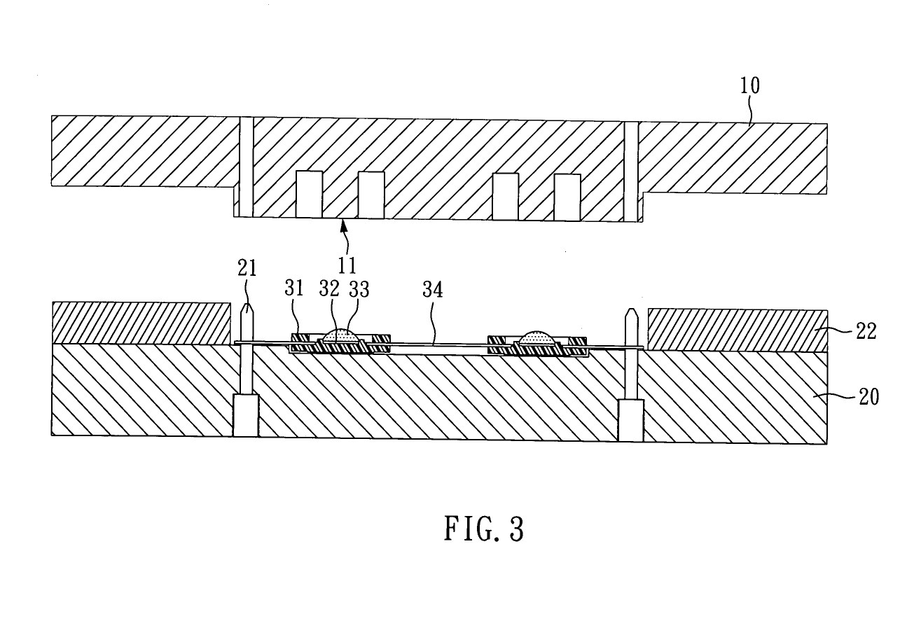

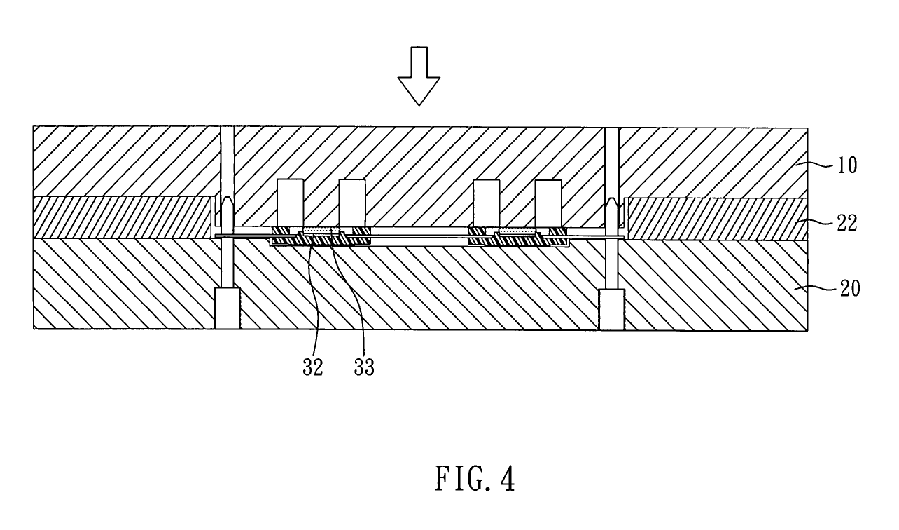

Further, referring to FIG. 1, a flowchart illustrating the method for forming an LED phosphor resin layer according to the first embodiment of the present invention, to FIG. 3, a schematic view illustrating an LED phosphor resin, not configurated yet, and to FIG. 4, a schematic view illustrating an LED phosphor resin, configurated already, the method for forming the LED phosphor resin layer comprises the following steps:

(A) Providing an upper mold 10 and a lower mold 20, wherein the upper mold 10 includes a plurality of attaching surfaces 11 for attaching a phosphor resin material 33 in the subsequent steps, and wherein the lower mold 20 includes a plurality of positioning pillars 21 and height-adding pads 22. Besides, the LED supports 31 are provided, wherein the LED supports 31 each supports an LED chip 32.

(B) Securing the LED supports 31 on the lower mold 20. In the present embodiment, the plural LED supports 31 are engaged with a conductive sheet 34. Therefore, providing plural positioning holes on the conductive sheet 34 which align with, and insert into, the positioning pillars 21 of the lower mold 20, the purpose of securing the LED supports 31 can be achieved.

(C) Dispensing a phosphor resin material 33 on the LED chip 32.

(D) Aligning the upper mold 10 with the lower mold 20. Since the lower mold 20 is provided beforehand with height-adding pads 22, when the two molds 10,20 are aligned with each other, the LED chips 32 and the attaching surfaces 11 will be apart from one another at a predetermined distance, respectively. In this stage, the phosphor resin material 33 in part contacts the LED chips 32 and in part attaches to the attaching surfaces 11 of the upper mold 10. Then the phosphor resin material 33 will have a thickness limited by the predetermined distance.

(D1) Fixing the upper mold 10 to the lower mold 20. In the present embodiment, screws 40 are adopted to achieve the purpose.

(E) Heating the phosphor resin material 33 which is then cured and formed as an LED phosphor resin layer. For instance, putting the molds 10,20, together with articles inside thereof, into an oven for heating. And after stripping the molds 10,20, phosphor resin layers can be formed on the LED chips 32 eventually.

It is understood, therefore, that an LED device made from the method according to the present invention includes a phosphor resin layer whose accuracy of thickness is determined by the accuracy of the molds 10,20 themselves, rather than by the technique of resin dispensation. Therefore, the LED device made from the method according to the present invention can obtain easily a desired phosphor resin layer thickness by increasing or decreasing the number of the height-adding pads 22. Besides, through actual work done, it is proved that the color temperature difference can be restricted in ±30K, together with a better color uniformity and improved lumens.

It should be noted that, as far as “providing the phosphor resin material 33” is concerned, the phosphor resin material can be first dispensed on the attaching surfaces 11 of the upper mold 10. To dispense the phosphor resin material 33 on the upper mold 10 will allow a least side spacing between the LED chip 32 and the LED support 31 without a possibility of spilling the phosphor resin material 33.

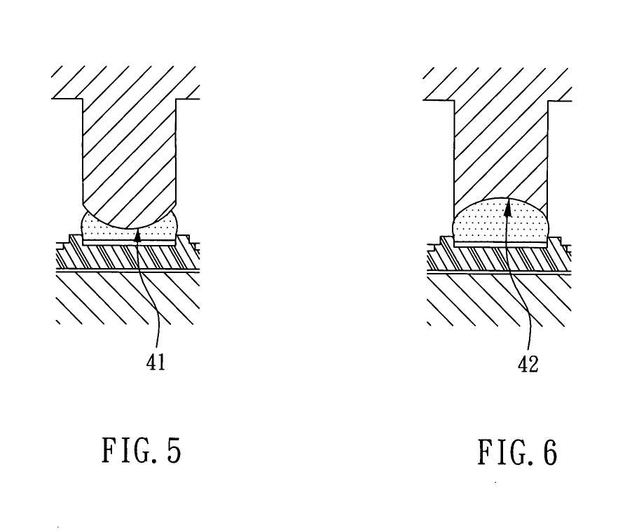

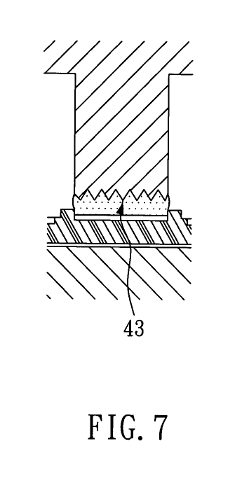

Further, the attaching surfaces 11 of the upper mold 10 may, flexibly, be pre-formed with optically related micro-structure, so that the phosphor resin layer can have a specific top configuration. An example in this respect may refer to FIG. 5, a schematic view illustrating an LED phosphor resin layer, configurated already, according to a second embodiment of the present invention, where by using an attaching surface 41 of convex configuration a phosphor resin layer of concave surface can be formed. Or, on the other hand, as shown in FIG. 6, a schematic view illustrating an LED phosphor resin layer, configurated already, according to a third embodiment of the present invention, where by using an attaching surface 42 of concave configuration a phosphor resin layer of convex surface can be formed. Now referring to FIG. 7, a schematic view illustrating an LED phosphor resin layer, configurated already, according to a fourth embodiment of the present invention, where by using an attaching surface 43 of comparatively complicated micro-structure a phosphor resin layer of micro-structure can be obtained.

In spite of the fact that in the above-mentioned embodiments references are made to the LED supports 31 with a bowl-like chip-receiving recess. The LED chip 32 may be received in an LED support of convex configuration.

Besides, according to the present invention, no matter the bowl-like chip-receiving recess has a greater or smaller bore, a predetermined phosphor resin layer can still be formed appropriately. The conventional art, however, does not have this merit. Through actual work done, it is proved that the phosphor resin layer made according to the present invention can have a thickness of 0.4 mm to 0.9 mm.

Although the present invention has been explained in relation to its preferred embodiments, it is to be understood that many other possible modifications and variations can be made without departing from the scope of the invention as hereinafter claimed.

What is claimed is:

1. A method for forming an LED phosphor resin layer, comprising the following steps:
(A) providing an upper mold, a lower mold, and an LED support, wherein the LED support supports an LED chip;
(B) securing the LED support on the lower mold;
(C) providing a phosphor resin material between the LED chip and an attaching surface of the upper mold;
(D) aligning the upper mold with the lower mold, such that the phosphor resin material in part contacts the LED chip and in part attaches to the attaching surface of the upper mold, and that the LED chip and the attaching surface are apart from each other at a predetermined distance; and
(E) heating the phosphor resin material so as to form an LED phosphor resin layer.

2. The method as claimed in claim 1, wherein the attaching surface is a plane.

3. The method as claimed in claim 1, wherein the attaching surface is a concave.

4. The method as claimed in claim 1, wherein the attaching surface is a convex.

5. The method as claimed in claim 1, further comprising step (D1), subsequent to step (D), fixing the upper mold to the lower mold.

6. The method as claimed in claim 5, wherein the upper mold is screwed to the lower mold.

7. The method as claimed in claim 1, wherein the predetermined distance in step (D) is 0.4 mm to 0.9 mm.

8. The method as claimed in claim 1, wherein step (C) refers to dispensing the phosphor resin material on the LED chip.

9. The method as claimed in claim 1, wherein step (C) refers to dispensing the phosphor resin material on the attaching surface.
